(19) United States
(12) Patent Application Publication
(10) Pub. No.: US 2024/0312824 A1
(43) Pub. Date: Sep. 19, 2024

(54) PROCESSING METHOD OF WAFER

(71) Applicant: DISCO CORPORATION, Tokyo (JP)

(72) Inventor: Masaru NAKAMURA, Tokyo (JP)

(21) Appl. No.: 18/581,575

(22) Filed: Feb. 20, 2024

(30) Foreign Application Priority Data
Mar. 13, 2023 (JP) 2023-038330

(51) Int. Cl. H01L 21/683; H01L 21/304; H01L 21/78

(52) U.S. Cl. CPC H01L 21/6836; H01L 21/304; H01L 21/78

(57) ABSTRACT

Disclosed is a processing method of a wafer having a first surface and a second surface by arranging a thermocompression bonding sheet on the first surface and processing the second surface. The processing method includes a plasma processing step of subjecting the first surface to plasma processing, and also subjecting a third surface of the thermocompression bonding sheet, the third surface facing the first surface, to plasma processing, a thermocompression bonding step of bringing the third surface into contact with the first surface, heating the thermocompression bonding sheet, and thermocompression bonding the thermocompression bonding sheet to the first surface, and a processing step of holding the wafer at the thermocompression bonding sheet on a chuck table with the second surface of the wafer exposed upward, and processing the second surface.

### BACKGROUND OF THE INVENTION

### Field of the Invention

The present invention relates to a processing method of a wafer, which has a first surface and a second surface on an opposite side to the first surface, by arranging a thermocompression bonding sheet on the first surface, and processing the second surface of the wafer.

### Description of the Related Art

A wafer with a plurality of devices such as integrated circuits (ICs) or large scale integration (LSI) formed in regions defined by a plurality of intersecting dividing lines on a front surface thereof is ground at a back surface thereof to a desired thickness, and is then divided into individual device chips, and the divided device chips are used in electronic equipment such as mobile phones or personal computers.

As the wafer is held at its front surface on a chuck table when grinding its back surface, a protective tape is arranged on the front surface of the wafer to avoid causing damage on the devices (see, for example, JP 2005-246491A).

There is however a problem that, if an adhesive layer is formed on a bonding surface of a protective tape to be bonded to a front surface of the wafer, portions of the adhesive layer remain on a front surface of the wafer and lower quality of device chips when after completion of grinding, the protective tape is peeled off from the wafer to divide the wafer into the individual device chips.

To deal with the above-described problem, the present assignee has proposed a technique that arranges a thermocompression bonding sheet, which has no adhesive layer, on a front surface of a wafer, heats the thermocompression boding sheet to allow its bonding surface to show a bonding force, and compression bonding the thermocompression bonding sheet to the front surface of the wafer (see, for example, JP 2019-186488A and JP 2019-186489A).

### SUMMARY OF THE INVENTION

However, the above-described thermocompression bonding sheet has no adhesive layer formed separately beforehand on the bonding surface. There is hence a problem that when processing a back surface of the wafer, the front surface of the wafer cannot always be stably protected because the bonding force to be shown by the heating is insufficient or the bonding force is reduced with time.

The present invention therefore has as an object thereof the provision of a processing method of a wafer having a first surface and a second surface on an opposite side to the first surface, which can always stably protect the first surface of the wafer when arranging a thermocompression bonding sheet on the first surface and processing the second surface.

In accordance with an aspect of the present invention, there is provided a processing method of a wafer having a first surface and a second surface on an opposite side to the first surface. The processing method includes arranging a thermocompression bonding sheet on the first surface of the wafer and processing the second surface of the wafer. The processing method includes a plasma processing step of subjecting the first surface of the wafer to plasma processing, and also subjecting a third surface of the thermocompression bonding sheet, the third surface facing the first surface, to plasma processing, a thermocompression bonding step of, after performing the plasma processing step, bringing the third surface into contact with the first surface, heating the thermocompression bonding sheet, and thermocompression bonding the thermocompression bonding sheet to the first surface of the wafer to obtain the wafer with the thermocompression bonding sheet thermocompression bonded thereon, and a processing step of, after performing the thermocompression bonding step, holding the wafer, with the thermocompression bonding sheet thermocompression bonded thereon, on a chuck table with the second surface of the wafer exposed upward, and processing the second surface.

Preferably, in the processing step, grinding processing may be applied to the second surface of the wafer.

Preferably, in the plasma processing step, atmospheric-pressure plasma processing may be applied.

According to the processing method of the present invention for the wafer having the first surface and the second surface on the opposite side to the first surface, the first surface of the wafer can be always stably protected when arranging the thermocompression bonding sheet on the first surface and processing the second surface.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting a manner of applying plasma processing to a wafer in a processing method according to a first embodiment of the present invention for the wafer;

FIG. 2 is a perspective view depicting a manner of applying plasma processing to a thermocompression bonding sheet in the processing method;

FIG. 3 is a perspective view depicting a manner of placing the wafer and the thermocompression bonding sheet on a chuck table to perform a thermocompression bonding step in the processing method;

FIG. 4A is a perspective view depicting a manner of bringing the wafer into contact at a first surface thereof with a third surface of the thermocompression bonding sheet, and heating the thermocompression bonding sheet in the processing method;

FIG. 4B is a perspective view depicting another manner of bringing the wafer into contact at the first surface thereof with the third surface of the thermocompression bonding sheet, and heating the thermocompression bonding sheet in the processing method;

FIG. 4C is a perspective view depicting a manner of thermocompression bonding the thermocompression bonding sheet to the first surface of the wafer in the processing method;

FIG. 5 is a perspective view depicting a manner of removing a portion of the thermocompression bonding sheet, the portion protruding out of the wafer, in the processing method;

FIG. 6A is a perspective view depicting a manner of holding the wafer, with the thermocompression bonding sheet thermocompression bonded thereon, at the thermocompression bonding sheet under suction on a chuck table in a processing step of the processing method; and

FIG. 6B is a perspective view depicting a manner of processing a second surface of the wafer in the processing step of the processing method.

### DETAILED DESCRIPTION OF THE PREFERRED EMBODIMENT

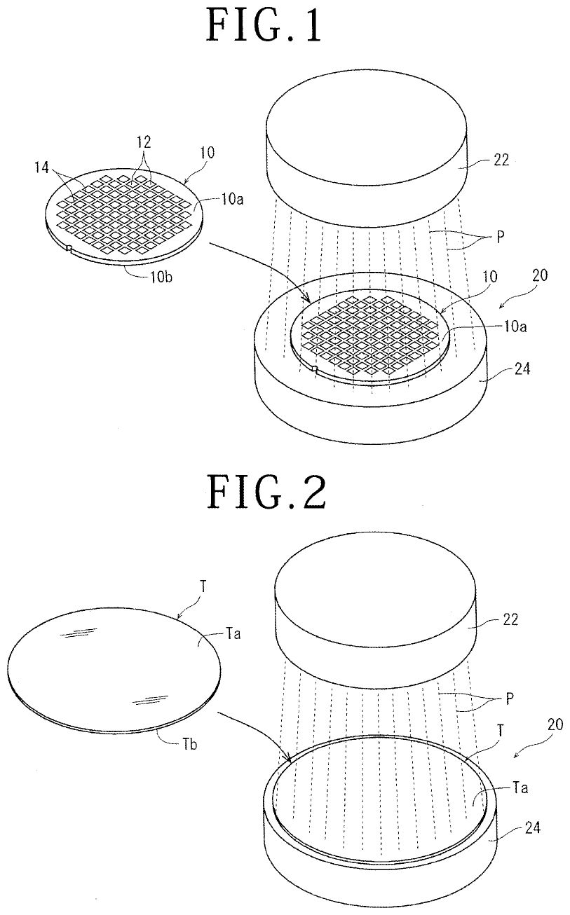

With reference to the attached drawings, a description will hereinafter be made in detail about a processing method according to an embodiment of the present invention for a wafer. On a left side of FIG. 1, a wafer 10 to be processed by the processing method of this embodiment is depicted. The wafer 10 is, for example, a silicon (Si) wafer, and a plurality of devices 12 are formed in regions defined by a plurality of intersecting dividing lines 14 on a first surface (front surface) 10a. In this embodiment, a second surface (back surface) 10b on an opposite side to the first surface 10a is processed in a processing step to be mentioned subsequently herein. It is to be noted that the wafer to be processed in accordance with the present invention is not limited to the above-described Si wafer, but may be a wafer of, for example, GaN, GaAs, or glass.

When performing the processing method of this embodiment, a thermocompression bonding sheet T as depicted in FIG. 2 is also provided in addition to the above-described wafer 10. The thermocompression bonding sheet T is a sheet to be thermocompression bonded to the first surface 10a of the wafer 10, and is selected from those which show a bonding force and also soften when heated to an appropriate temperature. The thermocompression bonding sheet T is selected, for example, from polyolefin-based sheets or polyester-based sheets. Examples of the polyolefin-based sheets usable as the thermocompression bonding sheet T include a polyethylene (PE) sheet, a polypropylene (PP) sheet, and a polystyrene (PS) sheet. On the other hand, Examples of the polyester-based sheets include a polyethylene terephthalate (PET) sheet and a polyethylene naphthalate (PEN) sheet.

The thermocompression bonding sheet T depicted in FIG. 2 is formed with a diameter greater than that of the wafer 10, and is a sheet that has no additional adhesive layer (glue layer) formed on any of a front surface or a back surface thereof, and shows a bonding force at the front surface when heated close to its melting point. The thermocompression bonding sheet T depicted in FIG. 2 has no substantial distinction between its front surface and back surface. For convenience of description, however, the front surface directed upward as seen in FIG. 2 will be referred to as a third surface Ta, and the back surface on the opposite side will be referred to as a fourth surface Tb. This embodiment will hereinafter be described assuming that a polyethylene sheet has been selected as the thermocompression bonding sheet T.

After the above-described wafer 10 and thermocompression bonding sheet T have been provided, the wafer 10 is transferred into a plasma system 20 depicted in FIG. 1. The plasma system 20 for use in this embodiment is an atmospheric-pressure plasma system that applies atmospheric-pressure plasma processing, and includes a plasma electrode 22 that forms a positive electrode, and a table 24 that forms an electrode opposing the plasma electrode 22 and capable of grounding the wafer 10, and has a holding surface capable of holding the wafer 10 or thermocompression bonding sheet T. The plasma system 20 is constructed such that the air flows between the plasma electrode 22 and the table 24.

After the wafer 10 has been transferred into the plasma system 20, the wafer 10 is placed at the second surface 10b on the table 24 with the first surface 10a directed upward. A high voltage is then applied across the above-described plasma electrode 22 and table 24, thereby generating a plasma P (plasmatized oxygen, plasmatized nitrogen, and the like) between the plasma electrode 22 and the table 24. By operating the plasma system 20 as described above, the plasma P acts on the first surface 10a of the wafer 10, so that organic matter stuck on the first surface 10a of the wafer 10 is destroyed and the first surface 10a is cleaned and activated.

After the plasma processing to the wafer 10 has been performed, the thermocompression bonding sheet T is also placed on the holding surface of the table 24 of the plasma system 20, with the third surface Ta and the fourth surface Tb being directed upward and downward, respectively, as depicted in FIG. 2, and in a similar manner as in the above, plasma processing is applied to the third surface Ta of the thermocompression bonding sheet T to cause the plasma P to act on the third surface Ta, so that organic matter stuck on the third surface Ta of the thermocompression bonding sheet T is destroyed and the third surface Ta is cleaned and activated. A plasma processing step has now been completed through the above-described plasma processing. It is to be noted that either the plasma processing to the wafer 10 or that to the thermocompression bonding sheet T may be performed first, or they may be concurrently performed in a plurality of plasma systems provided beforehand.

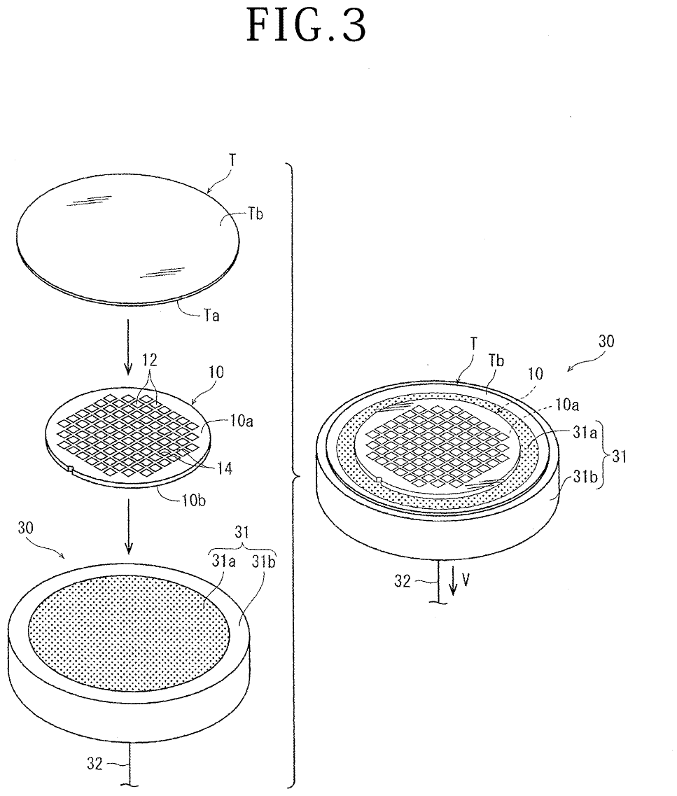

After the plasma processing step has been performed as described above, the wafer 10 and the thermocompression bonding sheet T are transferred into a thermocompression bonding device 30 fragmentarily depicted in FIG. 3. The thermocompression bonding device 30 includes a chuck table 31. As depicted in FIG. 3, the chuck table 31 is constructed including a suction chuck 31a formed of a porous member having air permeability, and a frame body 31b surrounding the suction chuck 31a, and is connected to suction means, free of illustration, via a communication path 32 connected to an inside of the frame body 31b. By operating the suction means, a negative pressure V can be created at an upper surface of the suction chuck 31a. As depicted in FIG. 3, the wafer 10 and thermocompression bonding sheet T are placed on the chuck table 31 by stacking the wafer 10 and the thermocompression bonding sheet T, so that the third surface Ta of the thermocompression bonding sheet T, the third surface Ta having been subjected to the plasma processing, comes into contact with the first surface 10a of the wafer 10, the first surface 10a having been subjected to the plasma processing.

As depicted in FIG. 3, the chuck table 31 is formed with a diameter greater than that of the wafer 10, the diameter of the thermocompression bonding sheet T is formed with a dimension greater than that of the suction chuck 31a of the chuck table 31, and as depicted on a right side of FIG. 3, the suction chuck 31a is covered in its entirety together with the wafer 10 by the thermocompression bonding sheet T. When the suction means is operated, the negative pressure V therefore acts between the thermocompression bonding sheet T and the chuck table 31, so that air is drawn from between the first surface 10a of the wafer 10 and the thermocompression bonding sheet T to create a vacuum state.

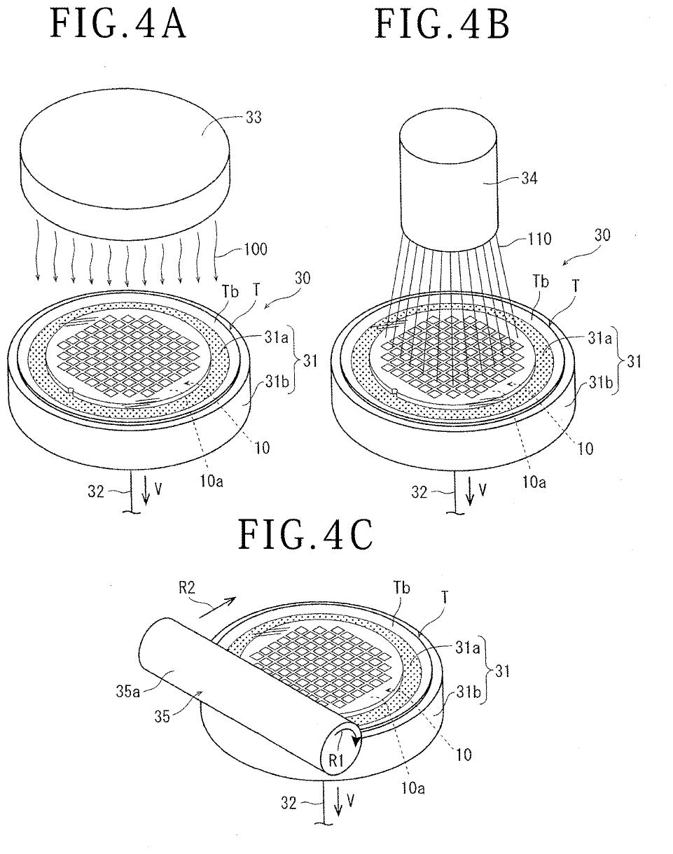

After the wafer 10 and thermocompression bonding sheet T have been held under suction on an upper surface of the chuck table 31, heating means arranged in the thermocompression bonding device 30, for example, an infrared heater 33 depicted in FIG. 4A is positioned above the chuck table 31. The infrared heater is then operated to irradiate and heat the upper surface of the chuck table 31 with infrared rays 100, so that the thermocompression bonding sheet T is heated to a temperature, which is close to a melting point of the polyethylene sheet making up the thermocompression bonding sheet T and at which the polyethylene sheet softens to show a bonding force, for example, 120° C. to 140° C.

It is to be noted that the heating means, which heats the thermocompression bonding sheet T, is not limited to the above-described infrared heater 33, but a warm air heater 34 depicted in FIG. 4B can be also used, for example. Instead of the infrared heater 33, the warm air heater 34 may be positioned above the chuck table 31, and warm air 110 may be blown against the thermocompression bonding sheet T to heat it to the above-described temperature at which the bonding force is shown.

After the thermocompression bonding sheet T has been heated as described above, a compression bonding roller 35 as depicted in FIG. 4C is positioned on and pressed against the thermocompression bonding sheet T held under suction on the chuck table 31. The compression bonding roller 35 is then moved in a direction indicated by an arrow R2 while rotating it in a direction indicated by an arrow R1, whereby the thermocompression bonding sheet T is thermocompression bonded to the entirety of the first surface 10a of the wafer 10, and a thermocompression bonding step is completed. It is to be noted that the compression bonding roller 35 is preferably coated at a surface 35a thereof with a fluororesin to avoid winding of the thermocompression bonding sheet T that shows the bonding force. Further, without separating the heating means (infrared heater 33 or warm air heater 34) and the compression bonding roller 35 as described above, a heater may be built in the compression bonding roller 35, and the thermocompression bonding sheet T may be compression bonded while being concurrently heated to a temperature at which the above-described bonding force is shown.

As described above, the plasma processing has been applied to the first surface 10a of the wafer 10 and the third surface Ta of the thermocompression bonding sheet T. Plasmatized oxygen, plasmatized nitrogen, and the like have therefore acted on the first surface 10a of the wafer 10 and the third surface Ta of the thermocompression bonding sheet T, so that the first surface 10a of the wafer 10 and the third surface Ta of the thermocompression bonding sheet T have been cleaned through destruction of organic matter, and have been activated. As a consequence, the first surface 10a of the wafer 10 and the third surface Ta of the thermocompression bonding sheet T, which have been subjected to the thermocompression bonding step and have been compression bonded together, are improved in bonding property compared with the related art in which no plasma processing step is applied.

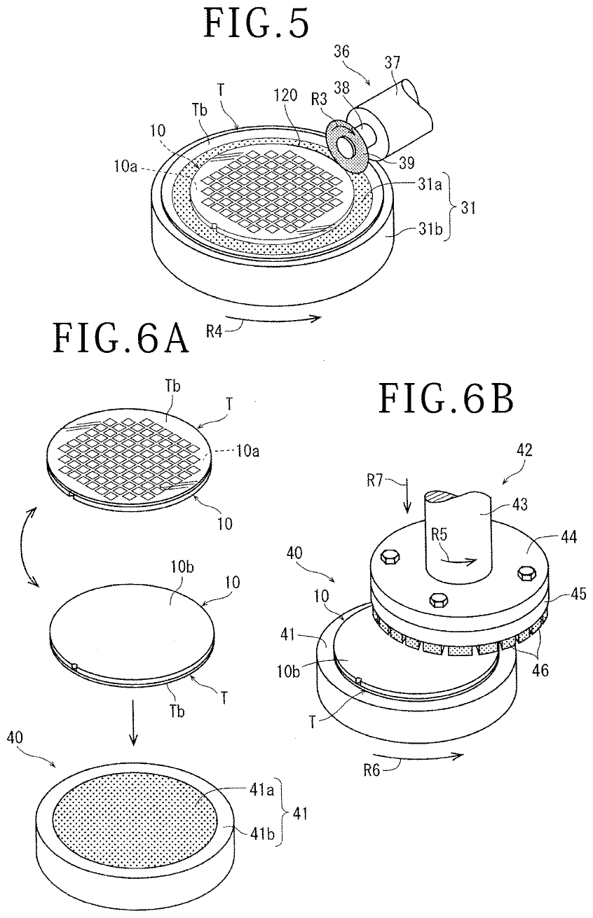

After the above-described thermocompression bonding step has been performed, a processing step is performed to process the second surface 10b of the wafer 10. Processing to be performed by the processing step in this embodiment is grinding processing that grinds the second surface 10b of the wafer 10. Before performing the grinding processing, a cutting unit 36 depicted in FIG. 5 is positioned above the chuck table 31. The cutting unit 36 includes a spindle housing 37 that rotatably holds a spindle 38, and a cutting blade 39 that is attached to a distal end of the spindle 38. The spindle 38 is rotated by a drive motor, free of illustration. With a tip of the cutting blade 39 positioned at an outer periphery of the wafer 10, the drive motor is operated to rotate the cutting blade 39 of the cutting unit 36 in a direction indicated by an arrow R3, and at the same time the chuck table 31 is rotated by an undepicted drive motor in a direction indicated by an arrow R4, whereby a cutting-in feed operation is performed. This enables to remove a portion of the thermocompression bonding sheet T, the portion protruding out of the outer periphery of the wafer 10.

It is to be noted that the thermocompression bonding step is performed by providing the thermocompression sheet T of a diameter greater than that of the wafer 10 in the above-described embodiment, but the present invention is not limited to such a thermocompression bonding sheet. It is possible to form the thermocompression bonding sheet T beforehand with the same diameter dimension as the wafer 10. According to this alternative, the thermocompression bonding step can be also performed by depressurizing an atmosphere into a vacuum to bring the thermocompression bonding sheet T and the wafer 10 into close contact with each other when bringing the thermocompression bonding sheet T and the wafer 10 into contact with each other, followed by heating the thermocompression bonding sheet T and then performing the thermocompression bonding step. If this is the case, it is possible to omit the above-described step in which the portion of the thermocompression bonding sheet T, the portion protruding out of the outer periphery of the wafer 10, is removed.

After the portion of the thermocompression bonding sheet T, the portion protruding out of the outer periphery of the wafer 10, has been removed as described above, the wafer 10 with the thermocompression bonding sheet T thermocompression bonded on the first surface 10a is transferred into a grinding apparatus 40 fragmentarily depicted in FIG. 6A. In the grinding apparatus 40, a chuck table 41 is arranged. The chuck table 41 includes a suction chuck 41a formed of a porous member having air permeability, and a frame body 41b surrounding the suction chuck 41a, and is connected to suction means, free of illustration, which creates a negative pressure V at an upper surface of the suction chuck 41a.

The wafer 10 which has been transferred onto the chuck table 41 of the grinding apparatus 40 is turned upside down as depicted in FIG. 6A, and is held at the thermocompression bonding sheet T (the fourth surface Tb) on the chuck table 41 with the first surface 10a, on which the thermocompression bonding sheet T has been thermocompression bonded, directed downward and the second surface 10b directed upward, whereby the second surface 10b of the wafer 10 is exposed upward. The suction means, free of illustration, is then operated, so that the wafer 10 is held under suction on the chuck table 41. As depicted in FIG. 6B, the chuck table 41 with the wafer 10 held under suction thereon is positioned at a location where the wafer 10 is to be subjected to grinding processing by the grinding apparatus 40.

The grinding apparatus 40 includes a grinding unit 42 that is for grinding the second surface 10b of the wafer 10 held under suction on the chuck table 41. The grinding unit 42 includes a rotating spindle 43 to be rotated by an undepicted rotary drive mechanism, a mounter 44 secured to a lower end of the rotating spindle 43, and a grinding wheel 45 attached to a lower surface of the mounter 44 and having a plurality of grinding stones arranged in an annular pattern on a side of a lower surface thereof.

After the wafer 10 has been held under suction on the chuck table 41, the chuck table 41 is rotated, for example, at 300 rpm in a direction indicated by an arrow R6 in FIG. 6B while rotating the rotating spindle 43 of the grinding unit 42, for example, at 6,000 rpm in a direction indicated by an arrow R5 in FIG. 6B. While supplying grinding water onto the second surface 10b of the wafer 10 by an undepicted grinding water supplying device, the grinding stones 46 are brought into contact with the second surface 10b of the wafer 10, and the grinding wheel 45 is fed for grinding at a grinding feed rate of, for example, 1 μm/sec toward a direction indicated by an arrow R7 (downward). Here, it is possible to proceed with the grinding while measuring the thickness of the wafer 10 by an undepicted, contact or non-contact measuring gauge. After the second surface 10b of the wafer 10 has been ground in a predetermined amount to a predetermined thickness, the grinding apparatus 40 is stopped, and through a rinsing step, a drying step, and like, a processing step of grinding the second surface 10b of the wafer 10 is completed, and therefore the processing method of this embodiment is completed.

In the processing method of this embodiment, plasma processing is applied to the first surface 10a of the wafer 10 and the third surface Ta of the thermocompression bonding sheet T, the third surface Ta being to face the first surface 10a, before performing the thermocompression bonding step as described above, so that they are both improved in bonding property. As a consequence, the thermocompression bonding sheet T held under suction on the chuck table 41 in the above-described processing step can always stably protect the first surface 10a of the wafer 10.

It is to be noted that although grinding processing is performed to grind the second surface 10b of the wafer 10 in the above-described processing step in this embodiment, the processing step in the present invention is not limited to grinding processing, but may perform, for example, polishing processing to polish the second surface 10b of the wafer 10.

In the embodiment described above, the description is made of the example in which the polyethylene sheet is selected as the thermocompression bonding sheet T with no adhesive layer formed thereon. However, the present invention is not limited to the example, but can use a polyolefin-based sheet of a different kind, or a polyester-based sheet. When heating the thermocompression bonding sheet T in the thermocompression bonding step, the heating temperature is preferably 160° C. to 180° C. if the thermocompression bonding sheet T is a polypropylene sheet, and is preferably 220° C. to 240° C. if the thermocompression bonding sheet T is a polystyrene sheet. Further, the heating temperature is preferably 250° C. to 270° C. if the thermocompression bonding sheet T is a polyethylene terephthalate sheet in the thermocompression bonding step, and the heating temperature is preferably 160° C. to 180° C. if the thermocompression bonding sheet T is a polyethylene naphthalate sheet in the thermocompression bonding step.

In the embodiment described above, the description is made of the example in which the atmospheric-pressure plasma system is adopted as the plasma system 20 that performs plasma processing. However, the present invention is not limited to the use of such an atmospheric-pressure plasma system but may use a vacuum plasma system. However, the adoption of the atmospheric-pressure plasma system allows to apply plasma processing with ease to the first surface 10a of the wafer 10 and the third surface Ta of the thermocompression bonding sheet T, and is therefore suited.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A processing method of a wafer having a first surface and a second surface on an opposite side to the first surface, including arranging a thermocompression bonding sheet on the first surface of the wafer and processing the second surface of the wafer, the processing method comprising:
a plasma processing step of subjecting the first surface of the wafer to plasma processing, and also subjecting a third surface of the thermocompression bonding sheet, the third surface facing the first surface, to plasma processing;
a thermocompression bonding step of, after performing the plasma processing step, bringing the third surface into contact with the first surface, heating the thermocompression bonding sheet, and thermocompression bonding the thermocompression bonding sheet to the first surface of the wafer to obtain the wafer with the thermocompression bonding sheet thermocompression bonded thereon; and
a processing step of, after performing the thermocompression bonding step, holding the wafer, with the thermocompression bonding sheet thermocompression bonded thereon, on a chuck table with the second surface of the wafer exposed upward, and processing the second surface.

2. The processing method according to claim 1, wherein, in the processing step, grinding processing is applied to the second surface of the wafer.

3. The processing method according to claim 1, wherein, in the plasma processing step, atmospheric-pressure plasma processing is applied.

4. The processing method according to claim 1, wherein the first surface of the wafer includes a plurality of devices formed, respectively, in regions defined by intersecting dividing lines.
